(19) United States
(12) Patent Application Publication
(10) Pub. No.: US 2007/0048668 A1
(43) Pub. Date: Mar. 1, 2007

(54) WAFER EDGE PATTERNING IN SEMICONDUCTOR STRUCTURE FABRICATION

(75) Inventor: Bernhard R. Liegl, Cold Spring, NY (US)

Correspondence Address: SCHMEISER, OLSEN & WATTS, 22 CENTURY HILL DRIVE, SUITE 302, LATHAM, NY, 12110, US

(73) Assignee: INTERNATIONAL BUSINESS MACHINES CORPORATION, Armonk, NY (US)

(21) Appl. No.: 11/162,006

(22) Filed: Aug. 25, 2005

(51) Int. Cl. G03F 7/20

(52) U.S. Cl. 430/311; 430/30; 430/394

(57) ABSTRACT

A lithographic process including providing a first wafer including (i) a first substrate, (ii) a first underlying layer on the first substrate, and (iii) a first resist layer on the first underlying layer; exposing a first plurality of full exposure fields of a first top resist layer plane through a product reticle, wherein the first top resist layer plane comprises a first top resist layer surface of the first resist layer, and wherein each full exposure field of the first plurality of full exposure fields is completely within the first top resist layer surface; and exposing a first plurality of partial exposure fields of the first top resist layer plane through a dummy reticle different from the product reticle, wherein each partial exposure field of the first plurality of partial exposure fields is partially but not totally within the first top resist layer surface.

### TECHNICAL FIELD

The present invention relates to semiconductor structure fabrication processes, and more specifically, to fabrication processes performed on wafer edge areas of a wafer.

### RELATED ART

The fabrication of multiple semiconductor integrated circuits (chips) on a semiconductor wafer can comprise many conventional fabrication steps each of which may not be uniformly performed throughout the entire wafer surface. For instance, a chemical mechanical polishing (CMP) step has the tendency to remove more materials on wafer edge areas than on other areas of the semiconductor wafer. If the semiconductor wafer is thinner at its edge than at other areas before the CMP step is performed, then the CMP step even makes it worse. Therefore, there is a need for improvements to the conventional fabrication steps.

### SUMMARY OF THE INVENTION

The present invention provides a structure fabrication method, comprising providing a first wafer including (i) a first substrate, (ii) a first underlying layer on the first substrate, and (iii) a first resist layer on the first underlying layer; exposing a first plurality of full exposure fields of a first top resist layer plane through a product reticle, wherein the first top resist layer plane comprises a first top resist layer surface of the first resist layer, and wherein each full exposure field of the first plurality of full exposure fields is completely within the first top resist layer surface; and exposing a first plurality of partial exposure fields of the first top resist layer plane through a dummy reticle different from the product reticle, wherein each partial exposure field of the first plurality of partial exposure fields is partially but not totally within the first top resist layer surface.

The present invention also provides a structure fabrication method, comprising providing a stepper system including first and second steppers, wherein the first stepper comprises a first reticle handling system holding a product reticle, and wherein the second stepper comprises a second reticle handling system holding a dummy reticle different from the product reticle; providing a first wafer including (i) a first substrate, (ii) a first underlying layer on the first substrate, and (iii) a first resist layer on the first underlying layer; placing the first wafer in the first stepper; exposing a first plurality of full exposure fields of a first top resist layer plane through the product reticle after said placing the first wafer in the first stepper is performed, wherein the first top resist layer plane comprises a first top resist layer surface of the first resist layer, and wherein each full exposure field of the first plurality of full exposure fields is completely within the first top resist layer surface; transferring the first wafer from the first stepper to the second stepper after said exposing the first plurality of full exposure fields; and exposing a first plurality of partial exposure fields of the first top resist layer plane through the dummy reticle after said transferring the first wafer is performed, wherein each partial exposure field of the first plurality of partial exposure fields is partially but not totally within the first top resist layer surface.

The present invention also provides a structure fabrication method, comprising providing a stepper system including first and second steppers, wherein the first stepper comprises a first reticle handling system holding a dummy reticle, and wherein the second stepper comprises a second reticle handling system holding a product reticle different from the product reticle; providing a first wafer including (i) a first substrate, (ii) a first underlying layer on the first substrate, and (iii) a first resist layer on the first underlying layer; placing the first wafer in the first stepper; exposing a first plurality of partial exposure fields of a first top resist layer plane through the dummy reticle after said placing the first wafer in the first stepper is performed, wherein the first top resist layer plane comprises a first top resist layer surface of the first resist layer, and wherein each partial exposure field of the first plurality of partial exposure fields is partially but not totally within the first top resist layer surface; transferring the first wafer from the first stepper to the second stepper after said exposing the first plurality of partial exposure fields; and exposing a first plurality of full exposure fields of the first top resist layer plane through the product reticle after said transferring the first wafer is performed, wherein each full exposure field of the first plurality of full exposure fields is completely within the first top resist layer surface.

The present invention provides improvements to the conventional fabrication steps.

### BRIEF DESCRIPTION OF THE DRAWINGS

FIGS. 1A-1B illustrate block diagrams of a first wafer processing system and its operation, in accordance with embodiments of the present invention.

FIG. 2 illustrates a top down view of a wafer that can be processed in the system of FIGS. 1A-1B, in accordance with embodiments of the present invention.

FIG. 3 illustrates a block diagram of a second wafer processing system, in accordance with embodiments of the present invention.

FIGS. 4A-4B illustrate one method to design a dummy reticle used in the systems of FIGS. 1A-1B and 3, in accordance with embodiments of the present invention.

### DETAILED DESCRIPTION OF THE INVENTION

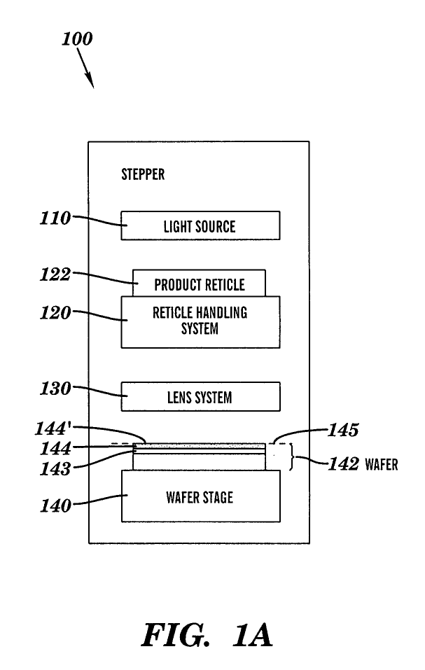

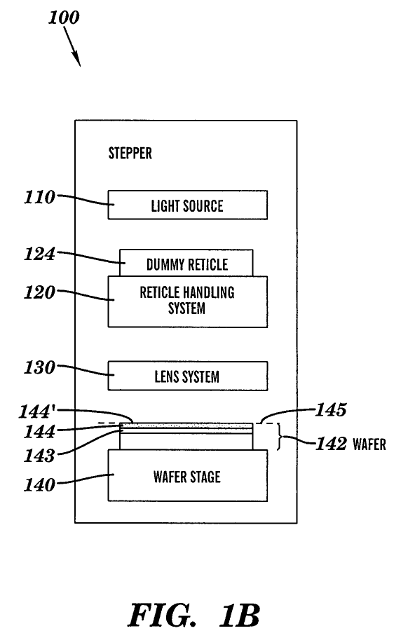

FIGS. 1A-1B illustrate a block diagram of a first wafer processing system 100 and its operation, in accordance with embodiments of the present invention. More specifically, with reference to FIGS. 1A-1B, in one embodiment, the system 100 is a step-and-repeat system (i.e., a stepper). In general, the system 100 can also be a step-and-scan system. The stepper 100 comprises, illustratively, a light source 110, a reticle handling system 120, a lens system 130, and a wafer stage 140. The light source 110, the reticle handling system 120, and the lens system 130 are stationary with reference to each other.

During the operation of the stepper 100, a wafer 142 to be etched is placed on the wafer stage 140 which is capable of holding and moving the wafer 142 with reference to the lens system 130. The wafer 142 comprises at its top (i) a layer 143 which is to be patterned and (ii) a resist layer 144 on top of the layer 143. For example, the layer 143 can be a dielectric layer in which contact holes need to be printed (i.e., created). The resist layer 144 has a top resist layer surface 144′. During the lithographic process performed on the resist layer 144, the wafer stage 140 adjusts the relative position of the wafer 142 such that the top resist layer surface 144′ is positioned in a focal plane 145 of the lens system 130.

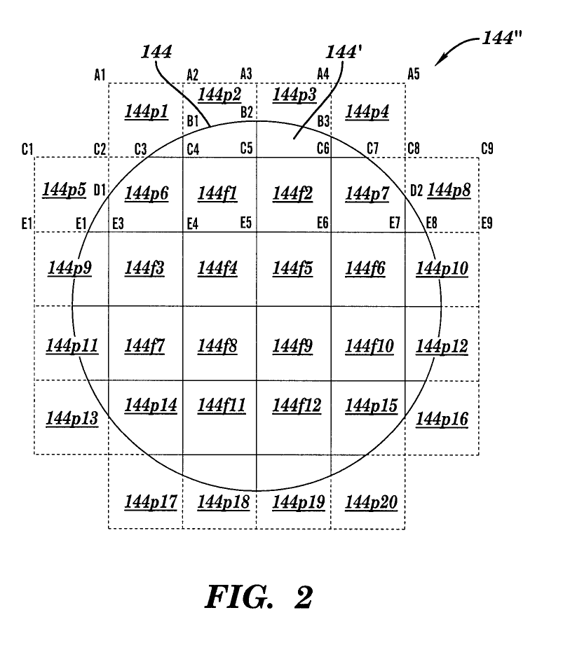

FIG. 2 illustrates a top down view of a top resist layer plane 144″ comprising the top resist layer surface 144′ of the wafer 142 (FIGS. 1A-1B), in accordance with embodiments of the present invention. With reference to FIGS. 1A, 1B, and 2, in one embodiment, the top resist layer plane 144″ is divided into multiple identical non-overlap exposure fields. Illustratively, each of the multiple identical non-overlap exposure fields has a rectangular shape as shown in FIG. 2. For example, some of the shown exposure fields are exposure fields A1A2C4C2 (144p1), A2A3C5C4 (144p2), C2C4E4E3 (144p6), and C4C5E5E4 (144f1).

The inventors of the present invention make the following definitions. A full exposure field is an exposure field that is completely within the top resist layer surface 144′ of the wafer 142. For example, exposure field C4C5E5E4 (144f1) is a full exposure field. In contrast, a partial exposure field is an exposure field that is only partially and not totally within the top resist layer surface 144′ of the wafer 142. For example, exposure fields A1A2C4C2 (144p1), A2A3C5C4 (144p2), C2C4E4E3 (144p6) are partial exposure fields. In FIG. 2, illustratively, there are 12 full exposure fields (namely, 144f1-144f12) and 20 partial exposure fields (namely, 144p1-144p20).

In one embodiment, devices are fabricated on the wafer 142 within the 12 full exposure fields 144f1-144f12, but no devices are fabricated on the wafer 142 within the 20 partial exposure fields 144p1-144p20. In one embodiment, one or more integrated circuits (ICs) can be fabricated on the wafer 142 within each of the 12 full exposure fields 144f1-144f12.

With reference to FIGS. 1A-1B and 2, in one embodiment, the operation of the stepper 100 is as follows.

First, a product reticle 122 is placed on and held in place by the reticle handling system 120. The product reticle 122 contains clear and opaque features that define the pattern of the product reticle 122 which is to be transferred to the resist layer 144 within each of the 12 full exposure fields 144f1-144f12.

Next, the wafer 142 is placed on and held tightly to the wafer stage 140. Then, the wafer stage 140 moves the wafer 142 to a relative position with respect to the lens system 130 such that (i) the top resist layer surface 144′ is in the focal plane 145 (where the image of the product reticle 122 resides) and (ii) only the full exposure field 144f1 will be exposed to light from the light source 110 through the product reticle 122 and the lens system 130.

Next, the full exposure field 144f1 is exposed to light from the light source 110 through the product reticle 122 and the lens system 130 such that the pattern of the product reticle 122 is transferred to the resist layer 144 within the full exposure field 144f1. It should be noted that the pattern of the product reticle 122 is defined by the clear and opaque features in the product reticle 122, whereas the pattern of the resist layer 144 is defined by the exposed and unexposed regions of the resist layer 144.

Next, in one embodiment, with the product reticle 122 still being held in place by the reticle handling system 120, the wafer stage 140 moves the wafer 142 to a relative position with respect to the lens system 130 such that (i) the top resist layer surface 144′ is in the focal plane 145 (where the image of the product reticle 122 resides) and (ii) only the full exposure field 144f2 will be exposed to light from the light source 110 through the product reticle 122 and the lens system 130.

Next, the full exposure field 144f2 is exposed to light from the light source 110 through the product reticle 122 and the lens system 130 such that the pattern of the product reticle 122 is transferred to the resist layer 144 within the full exposure field 144f2.

Next, with the product reticle 122 still being held in place by the reticle handling system 120, the 10 remaining full exposure fields 144f3-144f12 are sequentially (i.e., in turn) exposed in a similar manner such that the pattern of the product reticle 122 is in turn transferred to the resist layer 144 within the 10 full exposure fields 144f3-144f12. The process of sequentially exposing the full exposure fields 144f1-144f12 can be referred to as the full field exposure process.

Next, with the wafer 142 still being held to the wafer stage 140, the product reticle 122 is removed and replaced by a dummy reticle 124 (FIG. 1B). In one embodiment, the dummy reticle 124 contains clear and opaque features that define the pattern of the dummy reticle 124 which is to be transferred to the resist layer 144 within each of the 20 partial exposure fields 144p1-144p20.

Next, the wafer stage 140 moves the wafer 142 to a relative position with respect to the lens system 130 such that (i) the top resist layer surface 144′ is in the focal plane 145 (where the image of the dummy reticle 124 resides) and (ii) only the partial exposure field 144p1 will be exposed to light from the light source 110 through the dummy reticle 124 and the lens system 130.

Next, the partial exposure field 144p1 is exposed to light from the light source 110 through the dummy reticle 124 and the lens system 130 such that the pattern of the dummy reticle 124 is transferred to the resist layer 144 within the partial exposure field 144p1 (i.e., the region B1C4C3 of the resist layer 144).

Next, with the dummy reticle 124 still being held in place by the reticle handling system 120, the wafer stage 140 moves the wafer 142 to a relative position with respect to the lens system 130 such that (i) the top resist layer surface 144′ is in the focal plane 145 (where the image of the dummy reticle 124 resides) and (ii) only the partial exposure field 144p2 will be exposed to light from the light source 110 through the dummy reticle 124 and the lens system 130.

Next, the partial exposure field 144p2 is exposed to light from the light source 110 through the dummy reticle 124 and the lens system 130 such that the pattern of the dummy reticle 124 is transferred to the resist layer 144 within the partial exposure field 144p2 (i.e., the region B1B2C5C4 of the resist layer 144).

Next, with the dummy reticle 124 still being held in place by the reticle handling system 120, the 18 remaining partial exposure fields 144p3-144p20 are in turn exposed in a similar manner such that the pattern of the dummy reticle 124 is in turn transferred to the resist layer 144 within the 18 partial exposure fields 144p3-144p20. The process of sequentially exposing the partial exposure fields 144p1-144p20 can be referred to as the partial field exposure process.

Next, in one embodiment, the wafer 142 is removed from the stepper 100, and then the resist layer 144 is developed (i.e., patterned) in a developer (solvent). Next, the layer 143 underneath the patterned resist layer 144 is etched through the patterned resist layer 144.

In one embodiment, after the wafer 142 is removed from the stepper 100, the dummy reticle 124 is replaced by the product reticle 122 on the reticle handling system 120. Then, a second wafer (not shown) is placed on and held tightly to the wafer stage 140. Then, the second wafer undergoes the same fabrication process described above as the wafer 142. That is the second wafer undergoes the full field exposure process using the product reticle 122. Next, the product reticle 122 is replaced with the dummy reticle 124 on the reticle handling system 120, and then the second wafer undergoes the partial field exposure process using the dummy reticle 124.

Alternatively, after the wafer 142 is removed from the stepper 100, with the dummy reticle 124 still being held in place by the reticle handling system 120, the second wafer is placed on and held tightly to the wafer stage 140. Then, the second wafer undergoes the partial field exposure process using the dummy reticle 124. Next, the dummy reticle 124 is replaced with the product reticle 122 on the reticle handling system 120, and then the second wafer undergoes the full field exposure process using the product reticle 122. Next, after the second wafer is removed from the stepper 100, with the product reticle 122 still being held in place by the reticle handling system 120, a third wafer (not shown) is placed on and held tightly to the wafer stage 140. Then, the third wafer undergoes the full field exposure process using the product reticle 122. Next, the product reticle 122 is replaced with the dummy reticle 124 on the reticle handling system 120, and then the third wafer undergoes the partial field exposure process using the dummy reticle 124, and so on.

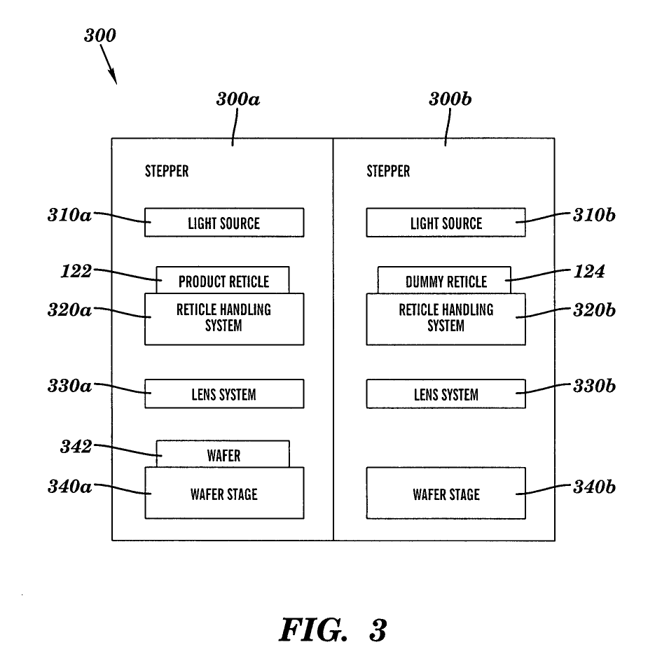

FIG. 3 illustrates a block diagram of a second wafer processing system 300, in accordance with embodiments of the present invention. In one embodiment, the second system 300 is a stepper system comprising two steppers 300a and 300b each of which is similar to the stepper 100 of FIGS. 1A-1B. For simplicity, all reference numerals herein have three numeric digits. In addition, similar regions have identical reference numerals except for the first digit which is used to indicate the numeric figure number. For example, the stepper 100 (FIGS. 1A-1B) and the stepper 300a (FIG. 3) are similar.

In one embodiment, the operation of the stepper system 300 is as follows. First, the product reticle 122 is placed on and held in place by the reticle handling system 320a while the dummy reticle 124 is placed on and held in place by the reticle handling system 320b.

Next, in one embodiment, a wafer 342 is placed on and held tightly to the wafer stage 340a. Then, the wafer 342 undergoes the full field exposure process in the stepper 300a. Next, the wafer 342 is transferred from the wafer stage 340a to the wafer stage 340b. Then, the wafer 342 undergoes the partial field exposure process in the stepper 300b before being removed from the stepper 300b for development.

In one embodiment, after the wafer 342 is transferred from the wafer stage 340a to the wafer stage 340b, another wafer (not shown) is placed on and held tightly to the wafer stage 340a and then undergoes the full field exposure process in the stepper 300a. Then, after the wafer 342 is removed from the stepper 300b for development, the another wafer is transferred to the wafer stage 340b to undergo the partial field exposure process in the stepper 300b.

In the embodiments described above, each wafer undergoes the full field exposure process in the stepper 300a first and then undergoes the partial field exposure process in the stepper 300b. Alternatively, each wafer undergoes the partial field exposure process in the stepper 300b first and then undergoes the full field exposure process in the stepper 300a.

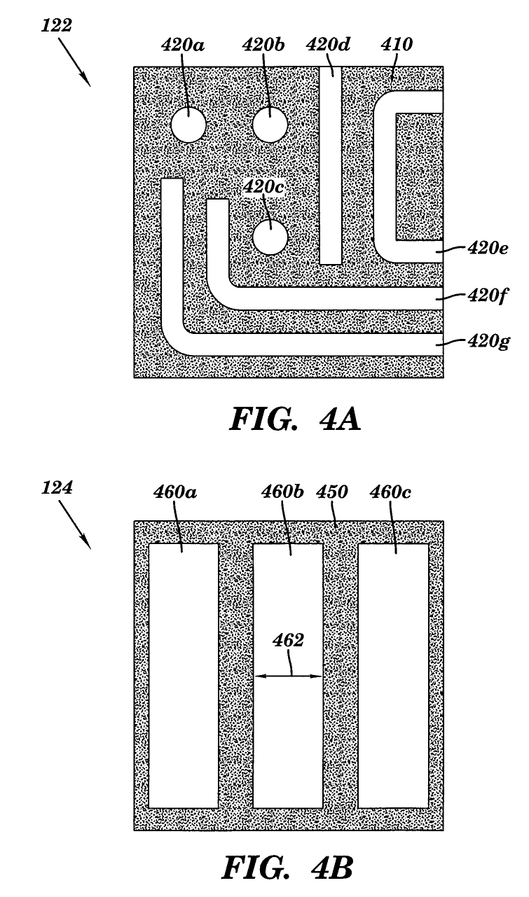

FIGS. 4A-4B illustrate a method to design the dummy reticle 124 based on the product reticle 122 for use in the systems 100 of FIGS. 1A-1B and the system 300 of FIG. 3, in accordance with embodiments of the present invention.

More specifically, the dummy reticle 124 and the product reticle 122 have the same pattern density. Here, the pattern density of a reticle is defined as the ratio of the area of clear features to the area of opaque features of the reticle. For illustration, assume that the product reticle 122 comprises seven clear regions 420a-420g in an opaque region 410. Then, in one embodiment, the dummy reticle 124 has the same size and shape as the product reticle 122. Moreover, the dummy reticle 124 is designed to comprise, illustratively, three (can be any positive integer in general) identical clear regions 460a, 460b, and 460c in a grating pattern in an opaque region 450 such that the total area of the clear regions 460a, 460b, and 460c is equal to the total area of the seven clear regions 420a-420g (i.e., the dummy reticle 124 and the product reticle 122 have the same pattern density).

In one embodiment, the width 462 of the clear regions 460a, 460b, and 460c in the grating pattern (i.e., the minimum feature size) is at least a pre-determined width such that the distortion degree in pattern transfer is less than a pre-specified acceptable distortion degree. Here, the distortion degree is defined as the percentage difference between the pattern density of a reticle and the pattern density of the underlying layer 143 patterned according to the reticle. Here, the pattern density of the underlying layer 143 for a specified region is defined as the ratio of the areas of the removed (etched) region to the total area of the specified region. In an ideal case, the distortion degree is zero.

In one embodiment, a relationship between the width 462 (i.e., the minimum feature size) and the distortion degree is determined from empirical data obtained through experiments. Usually, the larger the width 462, the smaller the distortion degree. Then, given a pre-specified acceptable distortion degree, the minimum width for the width 462 can be determined based on the pre-specified acceptable distortion degree and the relationship.

With reference to FIGS. 1A-1B, 2, and 4A-4B, it should be noted that because the partial exposure fields 144p1-144p20 correspond to wafer edge regions of the wafer 142 and because the wafer 142 usually becomes thinner and curved down toward its edge, therefore, the pattern being transferred from the dummy reticle 124 to the resist layer 144 in the wafer edge areas tends to be distorted or even disappear. However, because the width 462 is at least the pre-determined width such that the distortion degree in pattern transfer is less than the pre-specified acceptable distortion degree and because the dummy reticle 124 is area equivalent to the product reticle 122, therefore, the percentage difference between (a) the pattern transferred to the underlying layer 143 within the partial exposure fields 144p1-144p20 and (b) the pattern transferred to the underlying layer 143 within the full exposure fields 144f1-144f12 is less than the pre-specified acceptable distortion degree. This condition (i.e., essentially uniform pattern densities for the underlying layer 143 throughout different regions of the wafer 142) is very important for subsequent processes such as CMP (chemical mechanical polishing) whose quality depends greatly on the uniformity of the pattern density of the layer on which it is performed (i.e., underlying layer 143).

In summary, by using the product reticle 122 for the full field exposure process and using the dummy reticle 124 for the partial field exposure process and by ensuring that the dummy reticle 124 is area equivalent to the product reticle 122 but having minimum feature size (i.e., width 462) larger than the pre-determined width, the lithographic process performed on the underlying layer 143 results in the percentage difference between (a) the pattern transferred to the underlying layer 143 within the partial exposure fields 144p1-144p20 and (b) the pattern transferred to the underlying layer 143 within the full exposure fields 144f1-144f12 being less than the pre-specified acceptable distortion degree. This condition greatly improves the quality of subsequent processes such as CMP.

In the embodiments described above, optical lithography is used (i.e., the light source 110 is used). In general, non-optical lithography technologies can be used. For example, electron beam lithography, extreme Ultra-Violet lithography, X-Ray lithography, and ion-beam lithography can also be used.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A structure fabrication method, comprising:
providing a first wafer including (i) a first substrate, (ii) a first underlying layer on the first substrate, and (iii) a first resist layer on the first underlying layer;
exposing a first plurality of full exposure fields of a first top resist layer plane through a product reticle, wherein the first top resist layer plane comprises a first top resist layer surface of the first resist layer, and wherein each full exposure field of the first plurality of full exposure fields is completely within the first top resist layer surface; and
exposing a first plurality of partial exposure fields of the first top resist layer plane through a dummy reticle different from the product reticle, wherein each partial exposure field of the first plurality of partial exposure fields is partially but not totally within the first top resist layer surface.

2. The method of claim 1, wherein the first underlying layer comprises a dielectric material.

3. The method of claim 1, wherein said exposing the first plurality of full exposure fields and said exposing the first plurality of partial exposure fields are performed in a stepper nonsimultaneously.

4. The method of claim 3,
wherein said exposing the first plurality of full exposure fields is performed before said exposing the first plurality of partial exposure fields is performed,
wherein said exposing the first plurality of full exposure fields comprises placing the product reticle on a reticle handling system of the stepper, and
wherein said exposing the first plurality of partial exposure fields comprises replacing the product reticle with the dummy reticle on the reticle handling system of the stepper.

5. The method of claim 1,
wherein the dummy reticle and the product reticle have the same size and shape,
wherein the dummy reticle and the product reticle have a same pattern density, and
wherein a minimum feature size of the dummy reticle is at least a pre-determined width.

6. The method of claim 5, wherein the dummy reticle contains a grating pattern of identical clear regions.

7. The method of claim 1, further comprising, before said exposing the first plurality of partial exposure fields is performed:
determining a relationship between a distortion degree variable and a minimum feature size variable for dummy reticles;
specifying an acceptable distortion degree;
determining a minimum width for the minimum feature size variable based on the relationship and the specified acceptable distortion degree; and
providing the dummy reticle (i) with a minimum feature size of at least the determined minimum width, (ii) with a same pattern density as the product reticle, and (iii) having a same size and shape as the product reticle.

8. The method of claim 1, further comprising:
developing the first resist layer after said exposing the first plurality of full exposure fields and said exposing the first plurality of partial exposure fields are performed so as to create openings in the first resist layer; and
etching the first underlying layer through the openings in the first resist layer.

9. The method of claim 1, further comprising:
providing a second wafer including (i) a second substrate, (ii) a second underlying layer on the second substrate, and (iii) a second resist layer on the second underlying layer;
exposing a second plurality of partial exposure fields of a second top resist layer plane through the dummy reticle after said exposing the first plurality of full exposure fields and said exposing the first plurality of partial exposure fields are performed, wherein the second top resist layer plane comprises a second top resist layer surface of the second resist layer, wherein each partial exposure field of the second plurality of partial exposure fields is partially but not totally within the second top resist layer surface, and wherein said exposing the first plurality of full exposure fields is performed before said exposing the first plurality of partial exposure fields is performed; and
exposing a second plurality of full exposure fields of the second top resist layer plane through the product reticle after said exposing the second plurality of partial exposure fields is performed, wherein each full exposure field of the second plurality of full exposure fields is completely within the first top resist layer surface.

10. The method of claim 9,
wherein said exposing the first plurality of full exposure fields, said exposing the first plurality of partial exposure fields, said exposing the second plurality of full exposure fields, said exposing the second plurality of partial exposure fields are performed in a stepper nonsimultaneously,
wherein said exposing the first plurality of full exposure fields comprises placing the product reticle on a reticle handling system of the stepper,
wherein said exposing the first plurality of partial exposure fields comprises replacing the product reticle with the dummy reticle on the reticle handling system of the stepper, and
wherein said exposing the second plurality of full exposure fields comprises replacing the dummy reticle with the product reticle on the reticle handling system of the stepper.

11. The method of claim 1, further comprising:
providing a second wafer including (i) a second substrate, (ii) a second underlying layer on the second substrate, and (iii) a second resist layer on the second underlying layer;
exposing a second plurality of full exposure fields of a second top resist layer plane through the product reticle after said exposing the first plurality of full exposure fields and said exposing the first plurality of partial exposure fields are performed, wherein the second top resist layer plane comprises a second top resist layer surface of the second resist layer, wherein each full exposure field of the second plurality of full exposure fields is completely within the second top resist layer surface, and wherein said exposing the first plurality of full exposure fields is performed before said exposing the first plurality of partial exposure fields is performed; and
exposing a second plurality of partial exposure fields of the second top resist layer plane through the dummy reticle after said exposing the second plurality of full exposure fields is performed, wherein each partial exposure field of the second plurality of partial exposure fields is partially but not totally within the first top resist layer surface.

12. The method of claim 11,
wherein said exposing the first plurality of full exposure fields, said exposing the first plurality of partial exposure fields, said exposing the second plurality of full exposure fields, said exposing the second plurality of partial exposure fields are performed in a stepper nonsimultaneously,
wherein said exposing the first plurality of full exposure fields comprises placing the product reticle on a reticle handling system of the stepper,
wherein said exposing the first plurality of partial exposure fields comprises replacing the product reticle with the dummy reticle on the reticle handling system of the stepper,
wherein said exposing the second plurality of full exposure fields comprises replacing the dummy reticle with the product reticle on the reticle handling system of the stepper, and
wherein said exposing the second plurality of partial exposure fields comprises replacing the product reticle with the dummy reticle on the reticle handling system of the stepper.

13. The method of claim 1, wherein said exposing the first plurality of full exposure fields and said exposing the first plurality of partial exposure fields are optical lithographic processes.

14. The method of claim 1, wherein said exposing the first plurality of full exposure fields and said exposing the first plurality of partial exposure fields are non-optical lithographic processes.

15. A structure fabrication method, comprising:
providing a stepper system including first and second steppers, wherein the first stepper comprises a first reticle handling system holding a product reticle, and wherein the second stepper comprises a second reticle handling system holding a dummy reticle different from the product reticle;
providing a first wafer including (i) a first substrate, (ii) a first underlying layer on the first substrate, and (iii) a first resist layer on the first underlying layer;
placing the first wafer in the first stepper;
exposing a first plurality of full exposure fields of a first top resist layer plane through the product reticle after said placing the first wafer in the first stepper is performed, wherein the first top resist layer plane comprises a first top resist layer surface of the first resist layer, and wherein each full exposure field of the first plurality of full exposure fields is completely within the first top resist layer surface;
transferring the first wafer from the first stepper to the second stepper after said exposing the first plurality of full exposure fields; and
exposing a first plurality of partial exposure fields of the first top resist layer plane through the dummy reticle after said transferring the first wafer is performed, wherein each partial exposure field of the first plurality of partial exposure fields is partially but not totally within the first top resist layer surface.

16. The method of claim 15, further comprising:
developing the first resist layer after said exposing the first plurality of partial exposure fields is performed so as to create openings in the first resist layer; and
etching the first underlying layer through the openings in the first resist layer after said developing the first resist layer is performed.

17. The method of claim 15, wherein
providing a second wafer including (i) a second substrate, (ii) a second underlying layer on the second substrate, and (iii) a second resist layer on the second underlying layer;
placing the second wafer in the first stepper after said transferring the first wafer is performed;
exposing a second plurality of full exposure fields of a second top resist layer plane through the product reticle after said placing the second wafer in the first stepper is performed, wherein the second top resist layer plane comprises a second top resist layer surface of the second resist layer, and wherein each full exposure field of the second plurality of full exposure fields is completely within the second top resist layer surface;
transferring the second wafer from the first stepper to the second stepper after said exposing the second plurality of full exposure fields; and
exposing a second plurality of partial exposure fields of the second top resist layer plane through the dummy reticle after said transferring the second wafer is performed, wherein each partial exposure field of the second plurality of partial exposure fields is partially but not totally within the second top resist layer surface.

18. A structure fabrication method, comprising:
providing a stepper system including first and second steppers, wherein the first stepper comprises a first reticle handling system holding a dummy reticle, and wherein the second stepper comprises a second reticle handling system holding a product reticle different from the product reticle;
providing a first wafer including (i) a first substrate, (ii) a first underlying layer on the first substrate, and (iii) a first resist layer on the first underlying layer;
placing the first wafer in the first stepper;
exposing a first plurality of partial exposure fields of a first top resist layer plane through the dummy reticle after said placing the first wafer in the first stepper is performed, wherein the first top resist layer plane comprises a first top resist layer surface of the first resist layer, and wherein each partial exposure field of the first plurality of partial exposure fields is partially but not totally within the first top resist layer surface;
transferring the first wafer from the first stepper to the second stepper after said exposing the first plurality of partial exposure fields; and
exposing a first plurality of full exposure fields of the first top resist layer plane through the product reticle after said transferring the first wafer is performed, wherein each full exposure field of the first plurality of full exposure fields is completely within the first top resist layer surface.

19. The method of claim 18, further comprising:
developing the first resist layer after said exposing the first plurality of full exposure fields is performed so as to create openings in the first resist layer; and
etching the first underlying layer through the openings in the first resist layer after said developing the first resist layer is performed.

20. The method of claim 18, wherein
providing a second wafer including (i) a second substrate, (ii) a second underlying layer on the second substrate, and (iii) a second resist layer on the second underlying layer;
placing the second wafer in the first stepper after said transferring the first wafer is performed;
exposing a second plurality of partial exposure fields of a second top resist layer plane through the dummy reticle after said placing the second wafer in the first stepper is performed, wherein the second top resist layer plane comprises a second top resist layer surface of the second resist layer, and wherein each partial exposure field of the second plurality of partial exposure fields is partially but not totally within the second top resist layer surface;
transferring the second wafer from the first stepper to the second stepper after said exposing the second plurality of partial exposure fields; and
exposing a second plurality of full exposure fields of the second top resist layer plane through the product reticle after said transferring the second wafer is performed, wherein each full exposure field of the second plurality of full exposure fields is completely within the second top resist layer surface.
